(19) United States
(12) Patent Application Publication
(10) Pub. No.: US 2022/0075358 A1
(43) Pub. Date: Mar. 10, 2022

(54) ANALYSIS DEVICE, PLASMA PROCESS CONTROL SYSTEM, AND RECORDING MEDIUM

(71) Applicant: Tokyo Electron Limited, Tokyo (JP)

(72) Inventors: Ryu NAGAI, Miyagi (JP); Koki TANAKA, Miyagi (JP); Shuhei AKAHANE, Miyagi (JP)

(21) Appl. No.: 17/469,251

(22) Filed: Sep. 8, 2021

(30) Foreign Application Priority Data
Sep. 9, 2020 (JP) 2020-151545
Aug. 24, 2021 (JP) 2021-136576

(51) Int. Cl. G05B 19/418; G06K 9/62; H01L 21/3065

(52) U.S. Cl. CPC G05B 19/41885; G05B 19/4188; H01L 21/3065; G06K 9/6221; G05B 19/41865

(57) ABSTRACT

An analysis device includes: a calculation part configured to calculate a degree of deviation of a processing space, in which a plasma process is performed, from a reference condition by inputting, among time-series data groups measured in the processing space, a time-series data group measured in a determination section, which is a predetermined period of time before a control section, into a time-series analysis model; and a specifying part configured to specify a characteristic value for determining control data at a time of the plasma process of a substrate in the control section based on the calculated degree of deviation.

### CROSS-REFERENCE TO RELATED APPLICATIONS

This application is based upon and claims the benefit of priority from Japanese Patent Application No. 2020-151545, filed on Sep. 9, 2020 and Japanese Patent Application No. 2021-136576, filed on Aug. 24, 2021, the entire contents of which are incorporated herein by reference.

### TECHNICAL FIELD

The present disclosure relates to an analysis device, an analysis method, an analysis program, and a plasma process control system.

### BACKGROUND

In a semiconductor manufacturing process, changes in a condition of a processing space in which a plasma process is performed generally affect quality of a resultant product obtained when a workpiece is subjected to an etching process in the processing space. Therefore, in the etching process of the workpiece, it is important to quantitatively evaluate the condition of the processing space in order to maintain the quality of the resultant product.

In addition, in the processing space of the semiconductor manufacturing process, various data sets (data sets of a plurality of types of time-series data) (hereinafter, referred to as a “time-series data group”) are acquired before or during the etching process. The acquired time-series data group also includes time-series data that correlate with the condition of the processing space. However, it is difficult to evaluate the condition of the processing space by recognizing changes in individual time-series data.

### PRIOR ART DOCUMENT

### PATENT DOCUMENT

Patent Document 1: Japanese Laid-Open Patent Publication No. 2001-060585

### SUMMARY

An analysis device according to an aspect of the present disclosure includes: a calculation part configured to calculate a degree of deviation of a processing space, in which a plasma process is performed, from a reference condition by inputting, among time-series data groups measured in the processing space, a time-series data group measured in a determination section, which is a predetermined period of time before a control section, into a time-series analysis model; and a specifying part configured to specify a characteristic value for determining control data at a time of the plasma process of a substrate in the control section based on the calculated degree of deviation.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a first diagram illustrating an example of a system configuration of an etching process control system.

FIG. 2 is a first diagram illustrating a relationship of a flow of a plasma process in a processing space, a determination section, and a control section.

FIG. 3 is a view illustrating an example of a hardware configuration of an analysis device.

FIGS. 4A and 4B are views each illustrating an example of a time-series data group.

FIG. 5 is a first view illustrating a specific example of a process executed by a learning part.

FIG. 6 is a first view illustrating a specific example of a process executed by a specifying part.

FIGS. 7A and 7B are diagrams illustrating a correspondence relationship between a count value and an etching rate.

FIG. 8 is a first flowchart illustrating a flow of an analysis and control process.

FIG. 9 is a second diagram illustrating an example of a system configuration of an etching process control system.

FIG. 10 is a view illustrating an example of OES data.

FIG. 11 is a third diagram illustrating an example of a system configuration of an etching process control system.

FIG. 12 is a view illustrating an example of a process data group.

FIGS. 13A and 13B are second diagrams each illustrating a relationship of a flow of a plasma process in a processing space, a determination section, and a control section.

FIG. 14 is a second view illustrating a specific example of a process executed by the learning part.

FIG. 15 is a second view illustrating a specific example of a process executed by the specifying part.

FIGS. 16A and 16B are views illustrating specific examples of a degree of deviation.

FIG. 17 is a diagram illustrating a correspondence relationship between a degree of deviation and an etching rate.

FIG. 18 is a second flowchart illustrating a flow of the analysis and control process.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, each embodiment will be described with reference to the accompanying drawings. In addition, in the specification and drawings, constituent elements having substantially the same functional configurations will be denoted by the same reference numerals to omit redundant descriptions.

### FIRST EMBODIMENT

### System Configuration of Etching Process Control System

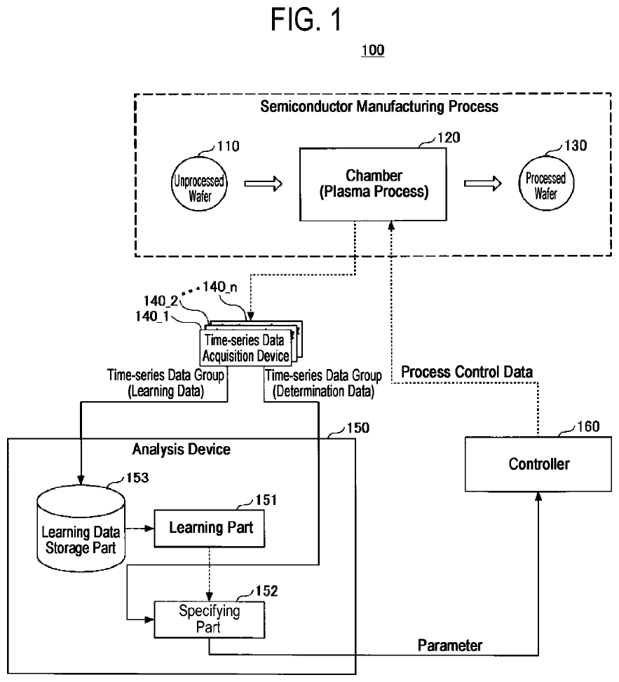

First, a system configuration of an etching process control system, which is an example of a plasma process control system, will be described. FIG. 1 is a first diagram illustrating an example of a system configuration of an etching process control system. As illustrated in FIG. 1, an etching process control system 100 includes a semiconductor manufacturing process, time-series data acquisition devices 140_1 to 140_n, an analysis device 150, and a controller 160.

In the semiconductor manufacturing process, a workpiece (an unprocessed wafer 110) is etched in a chamber 120, which is a processing space in which a plasma process is performed, and a resultant product (a processed wafer 130) is produced. Here, the “unprocessed wafer 110” refers to a wafer (a substrate) before being etched in the chamber 120, and the “processed wafer 130” refers to a wafer (a substrate) after being etched in the chamber 120.

Each of the time-series data acquisition devices 140_1 to 140_n measures time-series data before or during etching of the unprocessed wafer 110 in the chamber 120. It is assumed that the time-series data acquisition devices 140_1 to 140_n measure different types of measurement items from one another. The number of measurement items measured by each of the time-series data acquisition devices 140_1 to 140_n may be one or plural.

Among time-series data groups measured by the time-series data acquisition devices 140_1 to 140_n, a time-series data group measured when an etching process was performed under a normal condition, which serves as a reference of a condition of the chamber 120, by using a standard recipe (a predetermined specific recipe) is stored in a learning data storage part 153 as learning data.

In addition, among the time-series data groups measured by the time-series data acquisition devices 140_1 to 140_n, a time-series data group measured in a determination section is notified to a specifying part 152 as determination data.

The determination section refers to a section in which a time-series data group used for quantitatively evaluating the condition of the chamber 120 is measured during a plasma process performed in the chamber 120, and corresponds to a predetermined period of time prior to a control section to be described later.

An analysis program is installed in the analysis device 150, and when the program is executed, the analysis device 150 functions as the learning part 151 and the specifying part 152.

The learning part 151 performs machine learning on a time-series analysis model by using the learning data stored in the learning data storage part 153. The result of machine learning by the learning part 151 is notified to the specifying part 152 as a learned time-series analysis model.

The specifying part 152 calculates a degree of deviation of the condition of the chamber 120 from a reference condition in the determination section by inputting the time-series data group measured in the determination section by the time-series data acquisition devices 140_1 to 140_n into the learned time-series analysis model.

In addition, the specifying part 152 specifies, based on the degree of deviation from the reference condition, parameters (e.g., a characteristic value indicating process variation, such as an etching rate) for determining process control data at the time of the etching process in a control section after the determination section. That is, the specifying part 152 can quantitatively evaluate the condition of the chamber 120 in the determination section. In addition, the specifying part 152 notifies the controller 160 of the specified characteristic value (e.g., an etching rate).

The control section refers to a section, in which the etching process is performed by controlling the process control data (e.g., a gas flow rate, a temperature, a pressure, a plasma power supply voltage, a processing time, and the like) during the plasma process performed in the chamber 120, and corresponds to a section for an etching process after a determination section.

When the characteristic value (e.g., an etching rate) is notified from the specifying part 152 in the determination section, the controller 160 determines the process control data based on the characteristic value in the control section, and notifies the semiconductor manufacturing process of the process control data. Thus, the etching process in the chamber 120 can be controlled in the semiconductor manufacturing process.

As described above, the analysis device 150 specifies the characteristic value for determining the process control data at the time of the etching process by inputting the time-series data group measured in the determination section into the time-series analysis model and calculating the degree of deviation from the reference condition.

Therefore, it is possible to quantitatively evaluate the condition of the chamber 120 with the analysis device 150. In addition, with the analysis device 150, by quantitatively evaluating the condition of the chamber 120 and determining the process control data at the time of the etching process, it is possible to control the etching process in the control section based on the time-series data group in the determination section.

### Determination Section and Control Section

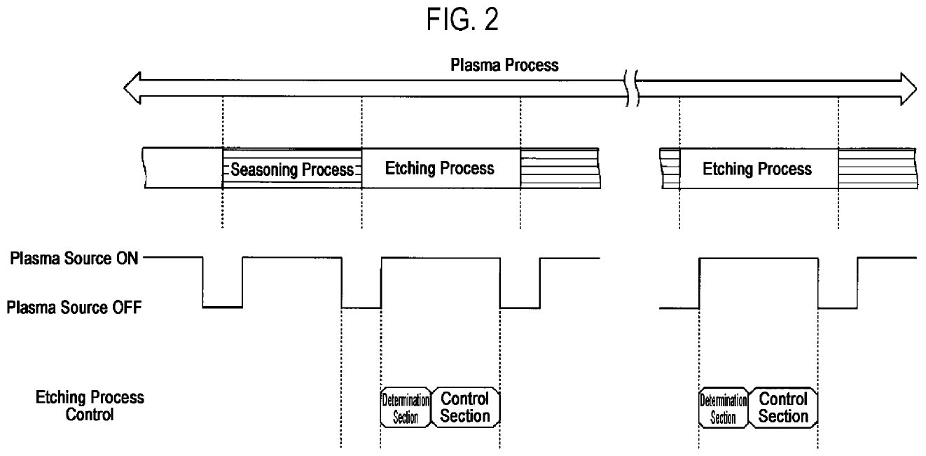

Next, a relationship among a flow of a plasma process in the chamber 120, a determination section, and a control section will be described. FIG. 2 is a first diagram illustrating a relationship among a flow of a plasma process in a processing space, a determination section, and a control section.

As illustrated in FIG. 2, in a plasma process performed in the chamber 120, a plurality of seasoning processes and a plurality of etching processes are repeated. In addition, in each process, ON/OFF of a plasma source is switched.

In the present embodiment, the time-series data acquisition devices 140_1 to 140_n measure determination data in each etching process by setting a predetermined period of time immediately after the plasma source is turned on (immediately after ignition) as a determination section. A length of the determination section may be set to a fixed value of, for example, about 1 to 3 seconds, or may be set at a predetermined ratio with respect to the processing time in the etching process. The length of the determination section may be changed depending on a process or a chamber.

As described above, the determination data measured in the determination section is notified to the specifying part 152 and input to the time-series analysis model to calculate the degree of deviation from the reference condition. Thus, the characteristic value (e.g., an etching rate) is specified.

As a result, the etching process in the control section immediately after the determination section is controlled by using the process control data determined based on the specified characteristic value (e.g., an etching rate).

That is, according to the present embodiment, at the time of an etching process, the condition of the chamber 120 immediately after the plasma source is turned on can be quantitatively evaluated, and the etching process in a subsequent control section can be controlled.

### Hardware Configuration of Analysis Device

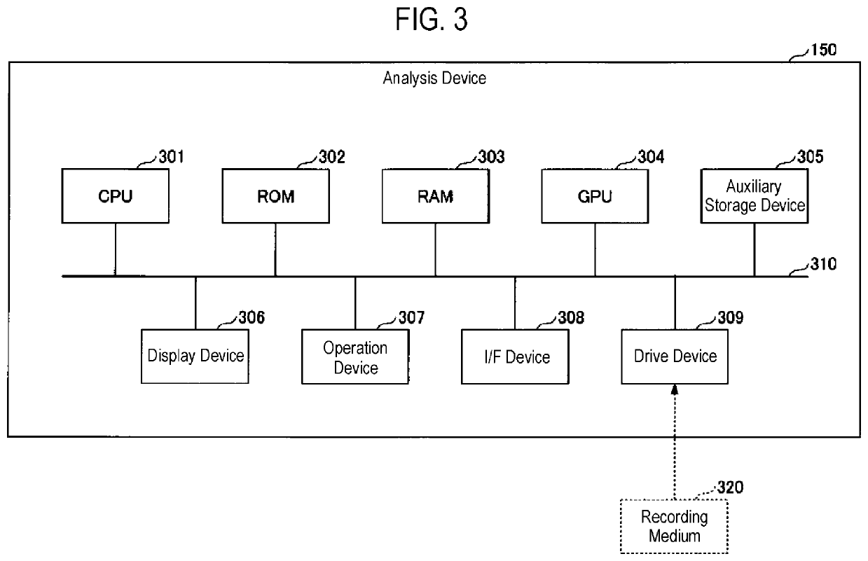

Next, a hardware configuration of the analysis device 150 will be described. FIG. 3 is a view illustrating an example of a hardware configuration of an analysis device. As illustrated in FIG. 3, the analysis device 150 includes a central processing unit (CPU) 301, a read only memory (ROM) 302, and a random access memory (RAM) 303. In addition, the analysis device 150 includes a graphics processing unit (GPU) 304. Processors (a processing circuit or a processing circuitry), such as the CPU 301 and the GPU 304, and memories, such as the ROM 302 and the RAM 303, form a so-called computer.

In addition, the analysis device 150 includes an auxiliary storage device 305, a display device 306, an operation device 307, an interface (I/F) device 308, and a drive device 309. Respective hardware components of the analysis device 150 are connected to one another via a bus 310.

The CPU 301 is an arithmetic device that executes various programs (e.g., an analysis program) installed in the auxiliary storage device 305.

The ROM 302 is a nonvolatile memory, and functions as a main storage device. The ROM 302 stores various programs and data necessary for the CPU 301 to execute various programs installed in the auxiliary storage device 305. Specifically, the ROM 302 stores, for example, a boot program such as a basic input/output system (BIOS) or an extensible firmware interface (EFI).

The RAM 303 is a volatile memory such as a dynamic random-access memory (DRAM) or a static random-access memory (SRAM), and functions as a main storage device. The RAM 303 provides a work region where various programs installed in the auxiliary storage device 305 are expanded when executed by the CPU 301.

The GPU 304 is an arithmetic device for image processing. In the present embodiment, when an analysis program is executed by the CPU 301, the GPU 304 performs a high-speed arithmetic operation by parallel processing on the time-series data groups. The GPU 304 is equipped with an internal memory (a GPU memory), and temporarily holds information necessary for performing the parallel processing on various time-series data groups.

The auxiliary storage device 305 stores, for example, various programs or various data used when the various programs are executed by the CPU 301. For example, the learning data storage part 153 is implemented in the auxiliary storage device 305.

The display device 306 displays an internal state of the analysis device 150. The operation device 307 is an input device used by a manager of the analysis device 150 to input various instructions to the analysis device 150. The I/F device 308 is a connection device for performing communication via a connection with a network (not illustrated).

The drive device 309 is a device for setting a recording medium 320. Here, the “recording medium 320” includes a non-transitory computer-readable medium for optically, electrically, or magnetically recording information, such as a CD-ROM, a flexible disk, or a magneto-optical disk. In addition, the recording medium 320 may include, for example, a semiconductor memory that electrically records information, such as, a ROM or a flash memory.

In addition, the various programs to be installed in the auxiliary storage device 305 are installed, for example, by setting a distributed recording medium 320 into the drive device 309 and reading out, by the drive device 309, the various programs recorded in the recording medium 320. Alternatively, the various programs to be installed in the auxiliary storage device 305 may be installed by being downloaded via a network (not illustrated).

### Specific Examples of Time-Series Data Group

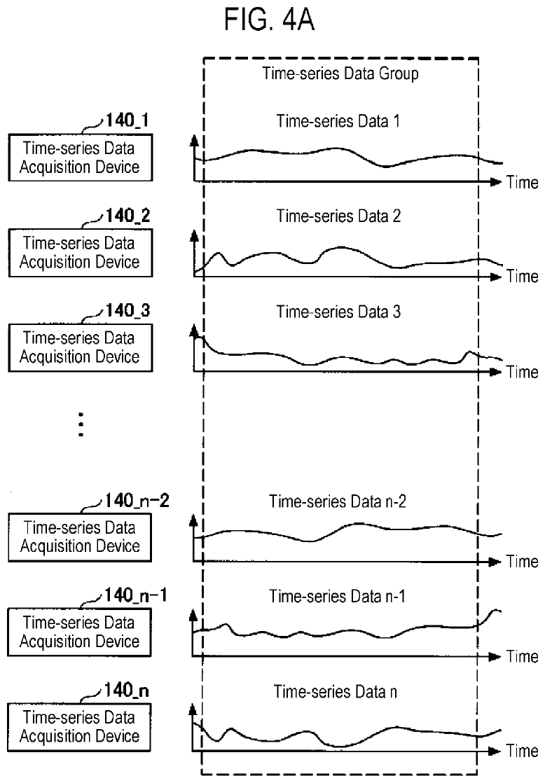

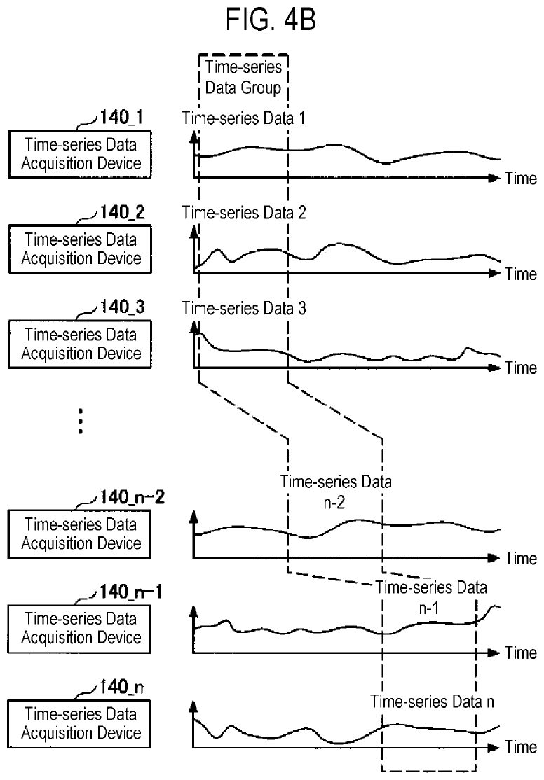

Next, specific examples of a time-series data group measured by the time-series data acquisition devices 140_1 to 140_n will be described. FIGS. 4A and 4B are views each illustrating an example of a time-series data group. In the example of each of FIGS. 4A and 4B, for simplification of description, it is illustrated that each of the time-series data acquisition devices 140_1 to 140_n measures one-dimensional data. However, a single time-series data acquisition device may measure two-dimensional data (a data set of a plurality of types of one-dimensional data).

FIG. 4A illustrates a time-series data group composed of time-series data measured in the same time range by the time-series data acquisition devices 140_1 to 140_n.

On the other hand, FIG. 4B illustrates a time-series data group composed of time-series data measured in corresponding time ranges by the time-series data acquisition devices 140_1 to 140_n. As illustrated in FIG. 4B, the learning data used for machine learning includes not only a time-series data group consisting of time-series data measured in the same time range, but also a time-series data group consisting of time-series data measured in corresponding time ranges.

### Specific Example of Process by Learning Part

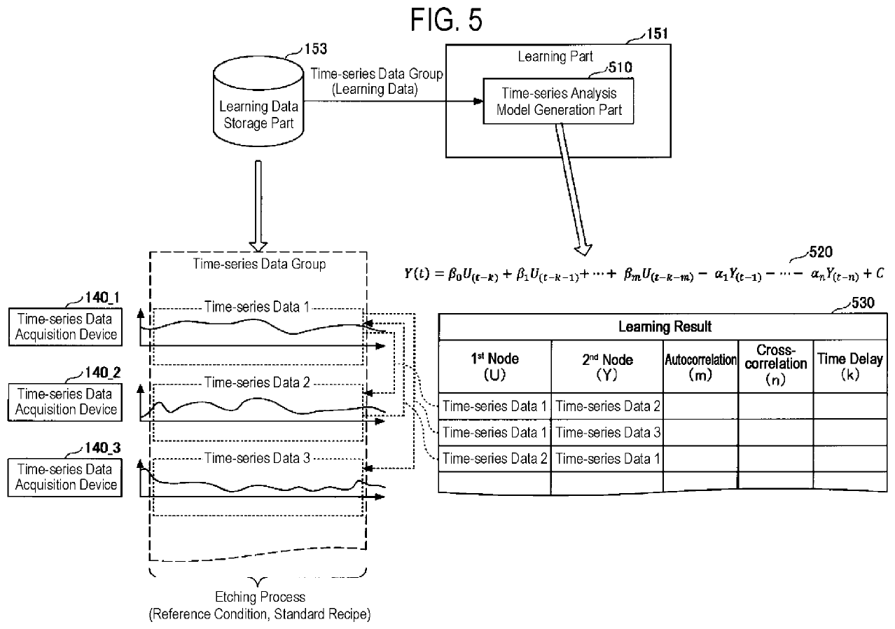

Next, a specific example of a process performed by the learning part 151 of the analysis device 150 will be described. FIG. 5 is a first view illustrating a specific example of a process executed by a learning part. As illustrated in FIG. 5, the learning part 151 has a time-series analysis model generation part 510.

The “time-series analysis model” referred to here is a machine learning model that comprehensively and quickly extracts a relationship of a plurality of time-series data from the same, and is a model that expresses the relationship of the plurality of time-series data by a linear regression or non-linear regression equation. An example of the time-series analysis model is a cross-correlation model. In the case of the cross-correlation model, a time delay term may be included in consideration of time differences of a plurality of time-series data.

The time-series analysis model generation part 510 specifies, by using an equation denoted by reference numeral 520, a relationship of time-series data of measurement items, which are measured by the respective time-series data acquisition devices 140_1 to 140_n when the etching process is performed by using the standard recipe under the reference condition.

Specifically, the time-series analysis model generation part 510 calculates respective coefficients (values indicating relationship) of the equation denoted by reference numeral 520, so that time-series data of a second node is derived by inputting time-series data of a first node into the equation denoted by reference numeral 520.

In the equation denoted by reference numeral 520, t represents time, m represents an autocorrelation (a coefficient indicating the presence or absence of periodicity), n represents a cross-correlation (a coefficient indicating whether or not time-series data are related to each other), k represents a time delay, and β, α, and C represent predetermined coefficients.

In FIG. 5, a learning result 530 shows respective coefficients (values indicating relationship), which are calculated by performing machine learning with respect to the time-series analysis model, of the equation denoted by reference numeral 520. Specifically, the learning result 530 includes “1^{st} Node,” “2^{nd} Node,” “Autocorrelation,” “Cross-correlation,” and “Time Delay” as information items.

In the learning result 530, among the time-series data groups included in the learning data, time-series data used to derive the equation denoted by reference numeral 520 are stored in each of the “1^{st} Node” and the “2ⁿNode.”

In the learning result 530, the coefficients m, n, and k, which are calculated to derive the time-series data of the second node by inputting the time-series data of the first node into the equation denoted by reference numeral 520, are stored in the “Autocorrelation,” the “Cross-correlation,” and the “Time Delay,” respectively.

As illustrated in FIG. 5, only one learning result 530 is generated with respect to the time-series data group (learning data) measured when the etching process is performed using the standard recipe under the reference condition.

### Specific Example of Process by Specifying Part

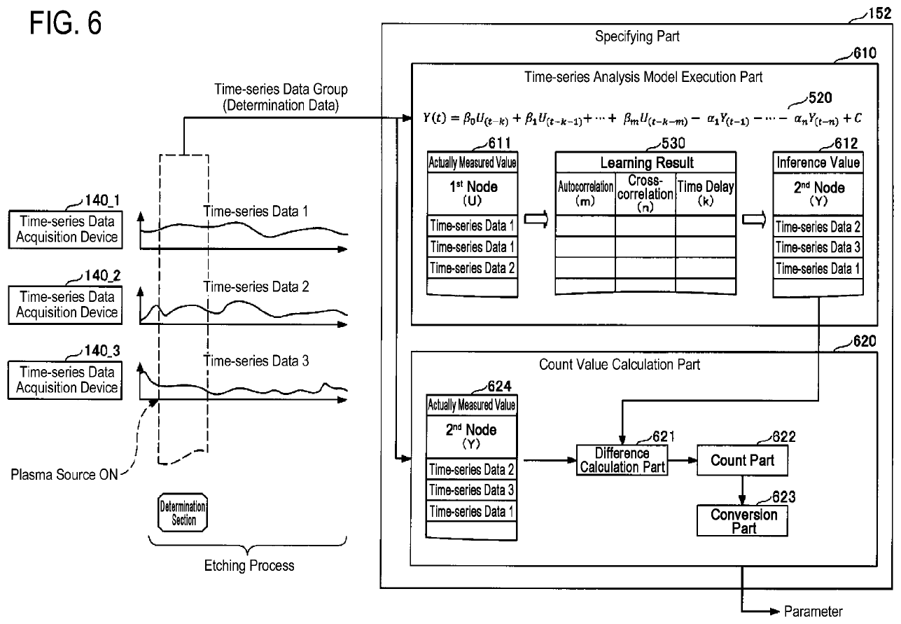

Next, a specific example of a process performed by the specifying part 152 of the analysis device 150 will be described. FIG. 6 is a first view illustrating a specific example of a process performed by the specifying part. As illustrated in FIG. 6, the specifying part 152 has a time-series analysis model execution part 610 and a count value calculation part 620.

The time-series analysis model execution part 610 extracts time-series data (an actually measured value 611) of the first node in a time-series data group (determination data) measured from a determination section immediately after the plasma source is turned on in the etching process. In addition, the time-series analysis model execution part 610 infers time-series data (an inference value 612) of the second node by inputting the extracted time-series data of the first node into the equation denoted by reference numeral 520.

At this time, the time-series analysis model execution part 610 reads the coefficients m, n, and k corresponding to the time-series data input into the equation denoted by reference numeral 520 from the learning result 530, sets the coefficients in the equation denoted by reference numeral 520, and then infers the time-series data of the second node.

In FIG. 6, the actually measured values 611 represent, of the time-series data group (determination data) measured in the determination section immediately after the plasma source is turned on in the etching process, the time-series data of the first node input into the equation denoted by reference numeral 520. In addition, the inference value 612 represents the time-series data of the second node inferred by inputting the actually measured value 611.

The count value calculation part 620 has a difference calculation part 621, a count part 622, and a conversion part 623.

The difference calculation part 621 extracts time-series data (actually measured values 624) of the second node from a time-series data group (determination data) measured in the determination section immediately after the plasma source is turned on in the etching process. In addition, the difference calculation part 621 acquires the inference value 612 from the time-series analysis model execution part 610. Furthermore, the difference calculation part 621 calculates a difference between the actually measured value 624 and the inferred value 612.

The count part 622 counts the number of first nodes at which the difference calculated by the difference calculation part 621 is equal to or greater than a predetermined threshold value (that is, a predetermined count value). In addition, the count part 622 outputs the counted predetermined count value as a degree of deviation of the condition of the chamber 120 from the reference condition in the determination section.

The conversion part 623 specifies a characteristic value (an etching rate) for determining process control data at the time of the etching process in the control section after the determination section, based on the degree of deviation of the condition of the chamber 120 from the reference condition in the determination section.

It is assumed that a correspondence relationship between the predetermined count value indicating the degree of deviation from the reference condition and the etching rate has been experimentally obtained in advance, and the conversion part 623 specifies the characteristic value (e.g., the etching rate) based on the correspondence relationship.

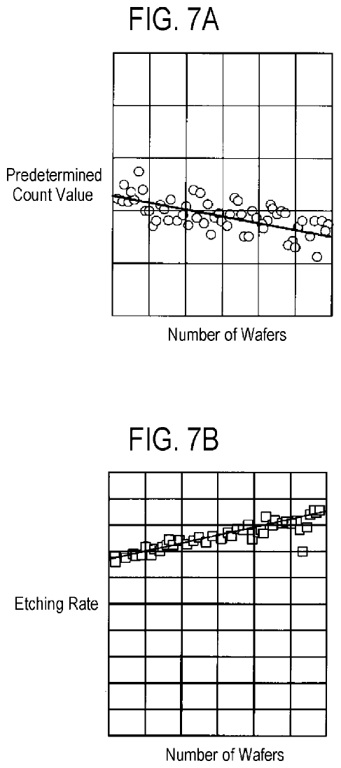

FIGS. 7A and 7B are diagrams illustrating a correspondence relationship between a predetermined count value and an etching rate. In FIG. 7A, the horizontal axis represents the number of etched wafers, and the vertical axis represents the predetermined count value. As illustrated in FIG. 7A, the number of wafers and the predetermined count value have a linear relationship.

In addition, in FIG. 7B, the horizontal axis represents the number of etched wafers, and the vertical axis represents an etching rate. As illustrated in FIG. 7B, the number of wafers and the etching rate have a linear relationship.

According to FIGS. 7A and 7B, the etching rate may be specified by counting the predetermined count value.

### Flow of Analysis and Control Process

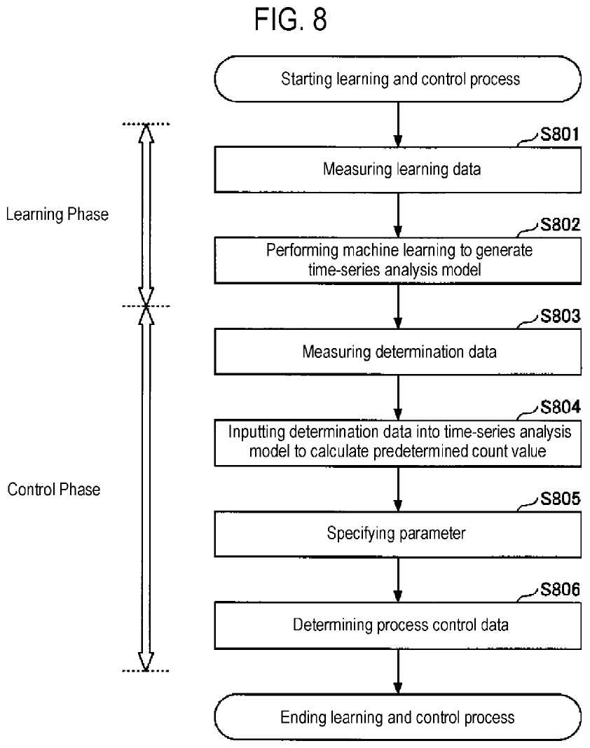

Next, a flow of an analysis and control process in the etching processing control system 100 will be described. FIG. 8 is a first flowchart illustrating a flow of an analysis and control process.

In step S801, the time-series data acquisition devices 140_1 to 140_n store, in the learning data storage part 153, the time-series data group (learning data) measured when the etching process is performed by using the standard recipe under the reference condition.

In step S802, the learning part 151 of the analysis device 150 performs machine learning with respect to the time-series analysis model by using the time-series data group (learning data) stored in the learning data storage part 153.

In step S803, when the etching process in the chamber 120 is started, the time-series data acquisition devices 140_1 to 140_n measure the time-series data group (determination data) in the determination section immediately after the plasma source is turned on.

In step S804, the specifying part 152 of the analysis device 150 inputs the time-series data group (determination data) measured in step S803 into the time series analysis model, and calculates the degree of deviation from the reference condition (i.e., counts the predetermined count value).

In step S805, the specifying part 152 of the analysis device 150 specifies the characteristic value (e.g., the etching rate) for determining the process control data at the time of the etching process in the control section after the determination section, based on the degree of deviation from the reference condition.

In step S806, the controller 160 determines the process control data at the time of the etching process in the control section based on the specified characteristic value.

As a result, in the semiconductor manufacturing process, the etching process in the control section can be controlled based on the determined process control data.

### Summary

As is clear from the above description, the etching process control system according to the first embodiment operates as follows:

calculating a degree of deviation of a chamber in which a plasma process is performed from a reference condition (i.e., counting a predetermined count value) by inputting, among time-series data groups measured in the chamber, a time-series data group measured in a determination section into a time-series analysis model;

specifying a characteristic value (an etching rate) for determining process control data at the time of an etching process in a control section after the determination section based on the calculated degree of deviation; and

controlling the etching process in the control section based on the specified characteristic value (the etching rate).

As a result, according to the first embodiment, it is possible to provide an analysis device, an analysis method, an analysis program, and an etching process control system for quantitatively evaluating a condition of a processing space in which a plasma process is performed by using a time-series data group measured in the processing space.

### SECOND EMBODIMENT

In the first embodiment, specific examples of the time-series data acquisition devices and the time-series data groups have not been mentioned. In contrast, in the second embodiment, a case in which an emission spectroscopic analyzer is used as a time series data acquisition device and a time series data group is optical emission spectroscopy (OES) data will be described. The OES data are a set of data including time-series data of emission intensity by a number corresponding to the number of types of wavelengths. Hereinafter, the second embodiment will be described by focusing on the differences from the first embodiment.

### System Configuration of Etching Process Control System

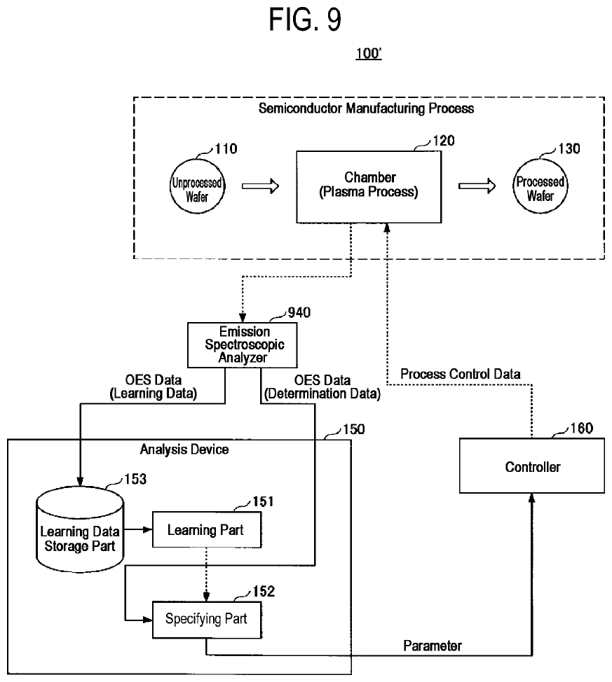

First, a system configuration of an etching process control system in a case in which OES data are used will be described. FIG. 9 is a second diagram illustrating an example of a system configuration of an etching process control system. A difference from FIG. 1 is that in the case of an etching process control system 100′, an emission spectroscopic analyzer 940 is provided as a time series data acquisition device. In addition, differences from FIG. 1 are that OES data are stored in the learning data storage part 153 as a time-series data group (learning data), and that the OES data are notified to the specifying part 152 as a time-series data group (determination data).

The emission spectroscopic analyzer 940 measures OES data before or during an etching process of an unprocessed wafer 110 in the chamber 120 by using an emission spectrophotometric technique. The OES data are, for example, time-series data indicating emission intensity of each wavelength included in the wavelength range of visible light at each time.

### Specific Example of OES Data

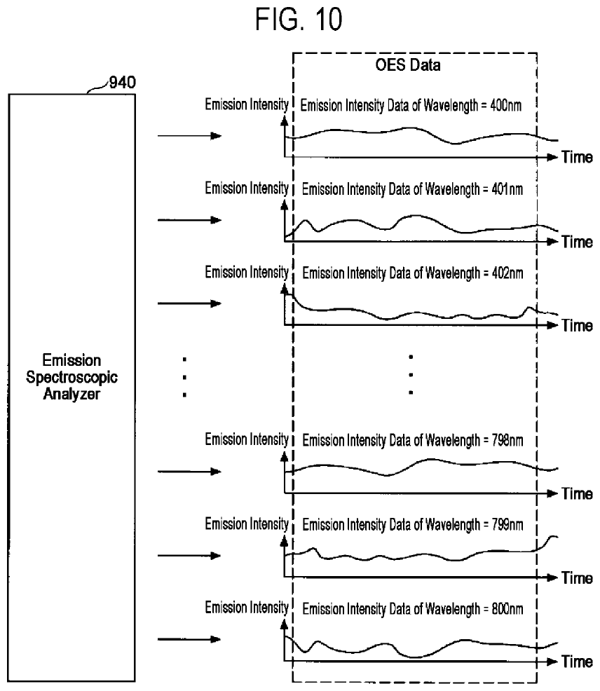

Next, a specific example of OES data measured by the emission spectroscopic analyzer 940 will be described. FIG. 10 is a view illustrating an example of OES data, and shows a light-emission intensity data group when each wavelength included in the wavelength range of visible light (400 nm to 800 nm) has been measured at an interval of 1 nm. In FIG. 10, the horizontal axis represents time and the vertical axis represents emission intensity of each wavelength.

In the case of FIG. 10, for example, the uppermost graph shows the emission intensity data of wavelength=400 nm at each time, and the graph in the second stage shows the emission intensity data of wavelength=401 nm at each time. In addition, the graph in the third stage in FIG. 10 shows the emission intensity data of wavelength=402 nm at each time.

By providing the emission spectroscopic analyzer 940 as a time-series data acquisition device as described above, with the etching process control system 100′ according to the second embodiment, the same processes as those of the first embodiment can be implemented.

As a result, according to the second embodiment, the same effect as that of the first embodiment can be obtained.

In the above description, the time-series data acquisition device is an emission spectrometric analyzer and the time-series data group is OES data. However, the time-series data acquisition device may be a mass analyzer (e.g., a quadrupole mass analyzer). In this case, the time-series data group is a data set including time-series data (mass analysis data) of detected intensity by a number corresponding to the number of types of mass-related values (m/z values).

### THIRD EMBODIMENT

In the second embodiment described above, the case in which the time series data group is OES data has been described. However, the time series data group is not limited to OES data, and may be, for example, a process data group (RF power supply data, pressure data, temperature data, and the like) measured by various process sensors.

Hereinafter, a third embodiment will be described by focusing on the differences from the first or second embodiment.

### System Configuration of Etching Process Control System

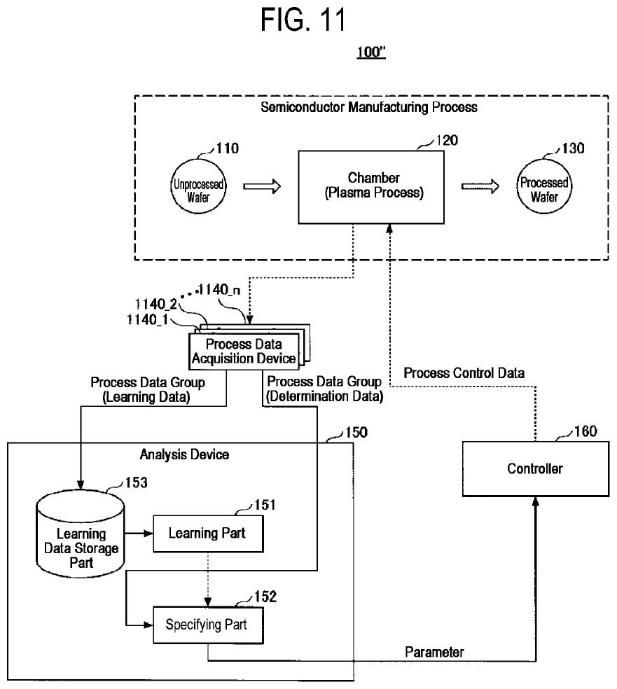

First, a system configuration of an etching processing control system in a case in which a process data group is used will be described. FIG. 11 is a third diagram illustrating an example of a system configuration of an etching process control system. A difference from FIG. 1 is that in the case of the etching process control system 100″, process data acquisition devices 1140_1, 1140_2, . . . , and 1140_n are provided as time-series data acquisition devices. In addition, differences from FIG. 1 are that a process data group is stored in the learning data storage part 153 as a time-series data group (learning data), and that the process data group is notified to the specifying part 152 as a time-series data group (determination data).

The process data acquisition devices 1140_1, 1140_2, . . . , and 1140_n measure a process data group before or during an etching process of an unprocessed wafer 110 in the chamber 120. The process data group includes, for example, RF power supply data, pressure data, gas flow rate data, current data, voltage data, temperature data, and the like at each time.

### Specific Example of Process Data Group

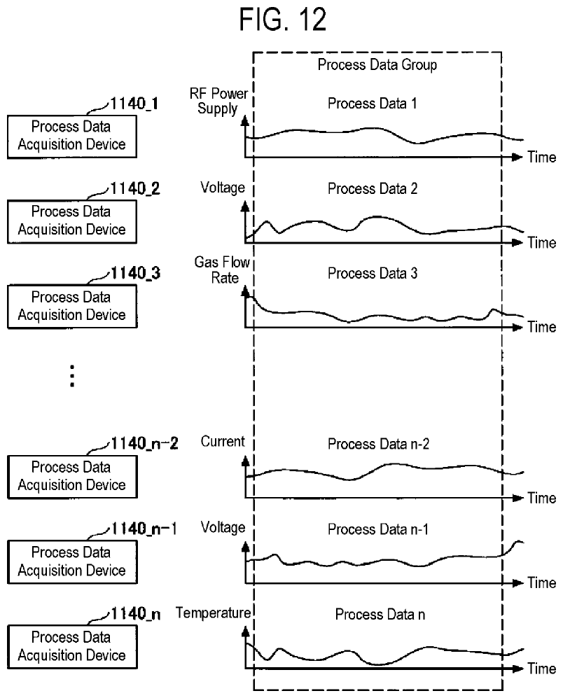

Next, a specific example of a process data group measured by the process data acquisition device 1140_1, 1140_2, . . . , and 1140_n will be described. FIG. 12 is a view illustrating an example of a process data group. In the example of FIG. 12, the process data acquisition device 1140_1 measures RF power supply data as process data 1 and the process data acquisition device 1140_2 measures pressure data as process data 2. Further, in the example of FIG. 12, the process data acquisition device 1140_3 measures gas flow rate data as process data 3.

Similarly, in the example of FIG. 12, the process data acquisition device 1140_n-2 measures current data as process data n-2, and the process data acquisition device 1140_n-1 measures voltage data as process data n-2. In addition, in the example of FIG. 12, the process data acquisition device 1140_n measures temperature data as process data n.

By providing the process data acquisition devices 1140_1 to 1140_n as the time-series data acquisition devices as described above, with the etching process control system 100″ according to the third embodiment, the same processes as those of the first embodiment can be implemented.

As a result, according to the third embodiment, the same effect as that of the first embodiment can be obtained.

### FOURTH EMBODIMENT

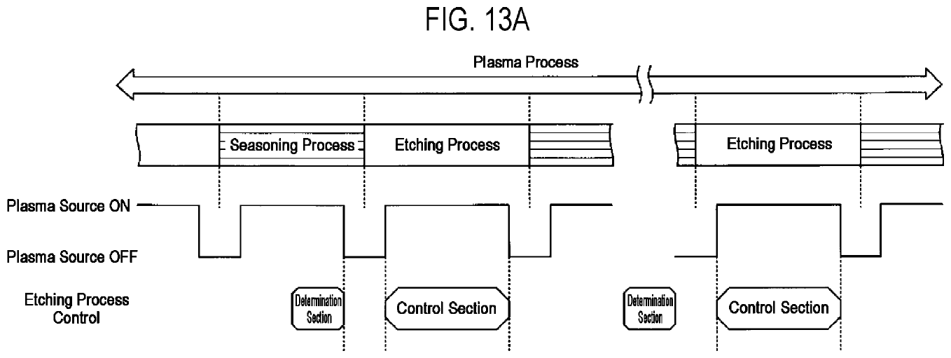

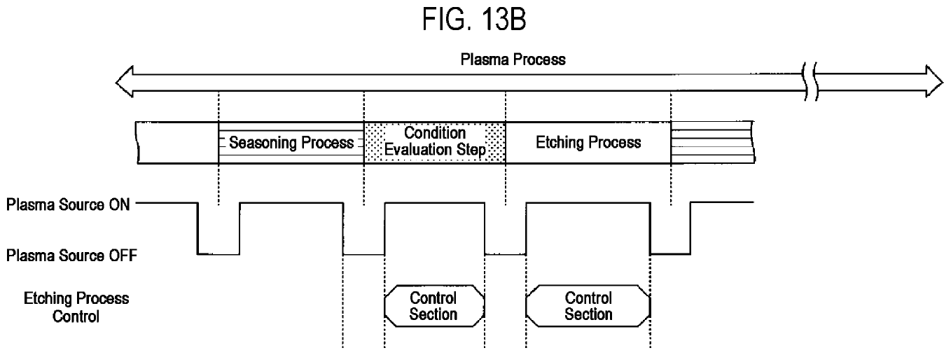

In the first to third embodiments described above, in the etching process, a predetermined period of time immediately after the plasma source is turned on is set as the determination section. However, the timing of the determination section is not limited thereto, and may be, for example, a predetermined period of time before the control section. FIGS. 13A and 13B are second diagrams each illustrating a relationship among a flow of a plasma process in a processing space, a determination section, and a control section.

FIG. 13A illustrates an example in which a predetermined period of time immediately before the plasma source is turned off is set as a determination section in a seasoning process. In this case, an etching process may be controlled by setting a section from the start to the end of the etching process as a control section and determining process control data by using a characteristic value specified based on a time-series data group (determination data) measured in the determination section.

FIG. 13B illustrates an example in which a process of evaluating a condition of the chamber 120 (a condition evaluation process) is provided between a seasoning process and an etching process, and the condition evaluation process is set as a determination section. In this case as well, the etching process may be controlled by setting a section from the start to the end of the etching process as a control section and determining process control data by using a characteristic value specified based on a time-series data group (determination data) measured in the determination section.

That is, according to the present embodiment, it is possible to control an etching process by quantitatively evaluating the condition of the chamber 120 based on a time-series data group in a predetermined period of time before starting the etching process.

### FIFTH EMBODIMENT

In the first to fourth embodiments, it has been described that a model that expresses the relationship of respective time series data by a linear regression equation or a non-linear regression equation is used as a time series analysis model. In contrast, in a fifth embodiment, instead of the time series analysis model, an abnormal value detection model that detects an abnormal value of data based on a data density of each time series data is used. Hereinafter, the fifth embodiment will be described by focusing on differences from the first to fourth embodiments. In the fifth embodiment, a case in which the time series data group is OES data will be described.

### Specific Example of Process by Learning Part

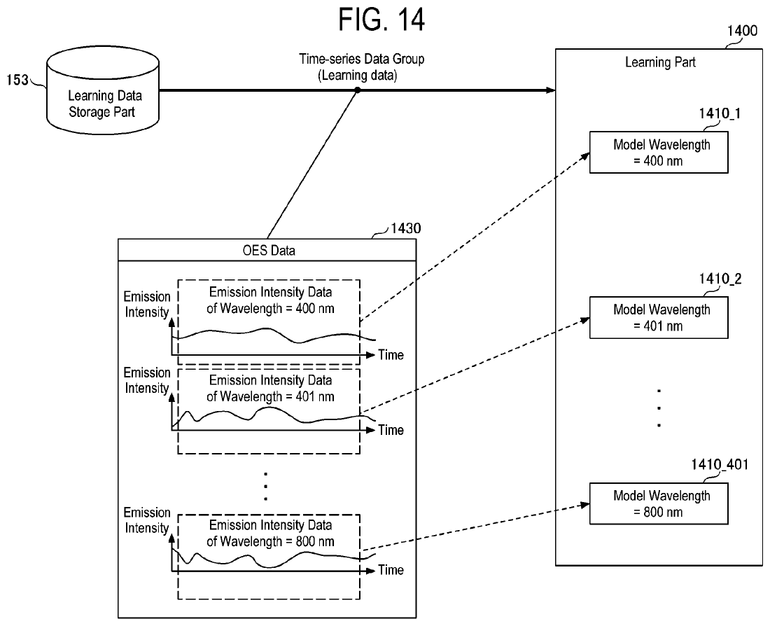

First, a specific example of a process executed by the learning part of the analysis device 150 will be described. FIG. 14 is a second view illustrating a specific example of a process executed by the learning part. As illustrated in FIG. 14, a learning part 1400 has a number of abnormal value detection models (models 1410_1 to 1410_401) corresponding to the number of types of wavelengths included in OES data 1430.

Among the OES data 1430 measured when an etching process was performed by using a standard recipe under a normal condition, which serves as a reference, time-series emission intensity data of the wavelength of 400 nm is input to the model 1410_1. As a result, the model 1410_1 calculates a data density of emission intensity data at each time. In addition, the model 1410_1 calculates a range of abnormal values under the normal condition, which serves as the reference. The range of abnormal values calculated by the model 1410_1 is set in a model 1510_1 (described later) as normal range information.

Similarly, among the OES data 1430 measured when the etching was performed by using the standard recipe under the normal condition serving as the reference, time-series emission intensity data of the wavelength of 401 nm is input to the model 1410_2. As a result, the model 1410_2 calculates a data density of the emission intensity data at each time. In addition, the model 1410_2 calculates a range of abnormal values under the normal condition, which serves as the reference. The range of abnormal values calculated by the model 1410_2 is set in a model 1510_2 (described later) as normal range information.

In FIG. 14, functional blocks for processing the emission intensity data of the wavelengths from 402 nm to 799 nm at each time are omitted. Thus, a description of these functional blocks will also be omitted below.

Among the OES data 1430 measured when the etching process was performed by using the standard recipe under the normal condition serving as the reference, time-series emission intensity data of the wavelength of 800 nm is input to the model 1410_401. As a result, the model 1410_401 calculates a data density of the emission intensity data at each time. In addition, the model 1410_401 calculates a range of abnormal values under the normal condition serving as the reference. The range of abnormal values calculated by the model 1410_401 is set in a model 1510_401 (described later) as normal range information.

### Specific Example of Process by Specifying Part

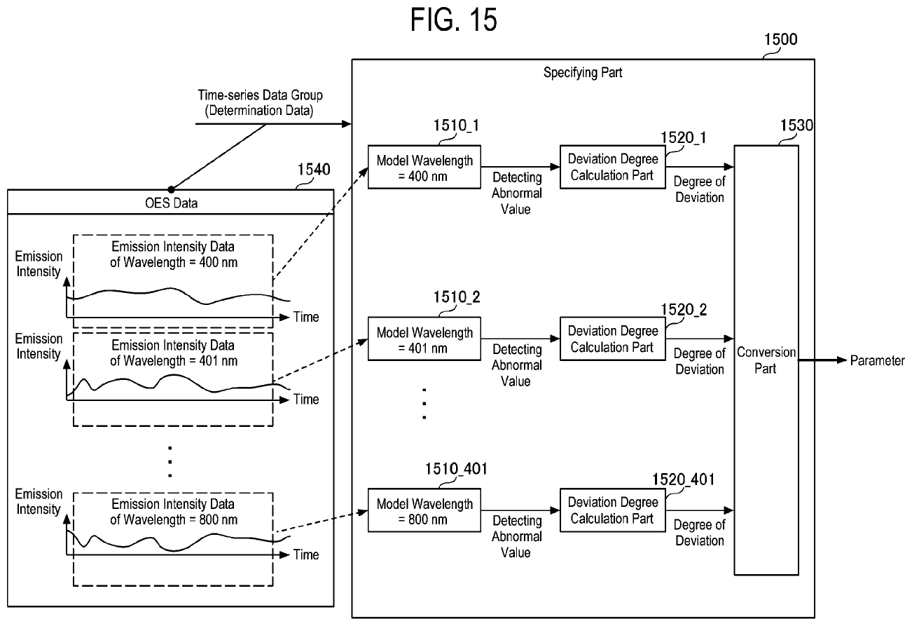

Next, a specific example of a process by the specifying part of the analysis device 150 will be described. FIG. 15 is a second view illustrating a specific example of a process executed by the specifying part. As illustrated in FIG. 15, the specifying part 1500 includes learned abnormal value detection models (models 1510_1 to 1510_401) and degree of deviation calculation parts (deviation degree calculation parts 1520_1 to 1520_401), where the numbers of the models 1510_1 to 1510_401 and the deviation degree calculation parts 1520_1 to 1520_401 correspond to the number of types of wavelengths included in the OES data 1540. In addition, the specifying part 1500 has a conversion part 1530.

Among the OES data 1540 measured by the emission spectroscopic analyzer 940 in the determination section, time-series emission intensity data of the wavelength of 400 nm is input to the model 1510_1. As a result, the model 1510_1 detects an abnormal value of the emission intensity data at each time based on the data density of the emission intensity data at each time. The model 1510_1 determines the presence or absence of the abnormal value in the emission intensity data at each time based on the set normal range information, and notifies the deviation degree calculation part 1520_1 of a determination result.

The deviation degree calculation part 1520_1 calculates a degree of deviation of the entire emission intensity data of the wavelength of 400 nm based on binary information indicating the presence or absence of the abnormal value notified from the model 1510_1, and notifies the conversion part 1530 of the calculated degree of deviation.

Similarly, among the OES data 1540 measured by the emission spectroscopic analyzer 940 in the determination section, the time-series emission intensity data of the wavelength of 401 nm is input to the model 1510_1. As a result, the model 1510_2 detects an abnormal value of the emission intensity data at each time based on the data density of the emission intensity data at each time. The model 1510_2 determines the presence or absence of an abnormal value in the emission intensity data at each time based on the set normal range information, and notifies the deviation degree calculation part 1520_2 of a determination result.

The deviation degree calculation part 1520_2 calculates a degree of deviation of the entire emission intensity data of the wavelength of 401 nm based on binary information indicating the presence or absence of the abnormal value notified from the model 1510_2, and notifies the conversion part 1530 of the calculated degree of deviation.

In FIG. 15, functional blocks for processing the emission intensity data of the wavelengths from 402 nm to 799 nm at each time are omitted. Thus, a description of these functional blocks will also be omitted below.

Among the OES data 1540 measured by the emission spectroscopic analyzer 940 in the determination section, the time-series emission intensity data of the wavelength of 800 nm is input to the model 1510_401. As a result, the model 1510_401 detects an abnormal value of the emission intensity data at each time based on the data density of the emission intensity data at each time. The model 1510_401 determines the presence or absence of an abnormal value in the emission intensity data of each time based on the set normal range information, and notifies the deviation degree calculation part 1520_401 of a determination result.

The deviation degree calculation part 1520_401 calculates a degree of deviation of the entire emission intensity data of the wavelength of 800 nm based on binary information indicating the presence or absence of the abnormal value notified from the model 1510_401, and notifies the conversion part 1530 of the calculated degree of deviation.

The conversion part 1530 specifies a deviation degree calculation part corresponding to a specific model among the models 1510_1 to 1510_401. In addition, the conversion part 1530 specifies a characteristic value (an etching rate) for determining process control data at the time of an etching process in a control section, based on the degree of deviation notified from the deviation degree calculation part.

A correspondence relationship between the degree of deviation, which is output from the deviation degree calculation part corresponding to the specific model among the deviation degree calculation parts 1520_1 to 1520_401, and the etching rate is experimentally obtained in advance. Further, the conversion part 1530 specifies the characteristic value (e.g., the etching rate) based on the experimentally obtained correspondence relationship.

### Specific Example of Degree of Deviation

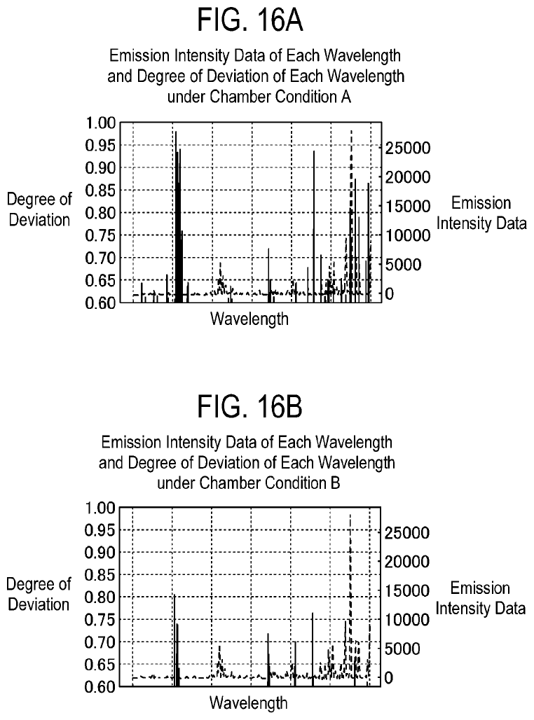

Next, specific examples of the degrees of deviation, each of which is output from each of the deviation degree calculation parts 1520_1 to 1520_401 will be described. FIGS. 16A and 16B are views illustrating specific examples of the degree of deviation. In each of FIGS. 16A and 16B, the horizontal axis represents types of wavelengths. The vertical axis represents emission intensity data of each wavelength at a predetermined time and a degree of deviation of the entire emission intensity data of each wavelength.

FIG. 16A illustrates emission intensity data of each wavelength and a degree of deviation of the entire emission intensity data of each wavelength calculated when the models 1510_1 to 1510_401 are applied to the emission intensity data of each wavelength, under a chamber condition A.

FIG. 16B illustrates emission intensity data of each wavelength and a degree of deviation of the entire emission intensity data of each wavelength calculated when the models 1510_1 to 1510_401 are applied to the emission intensity data of each wavelength, under a chamber condition B. It is known that the chamber condition A and the chamber condition B are different conditions from each other.

In FIG. 16A and FIG. 16B, the emission intensity data of wavelengths are similar to each other, but the degrees of deviation of emission intensity of specific wavelengths are significantly different from each other. That is, it can be said that a degree of deviation output from a specific deviation degree calculation part among the deviation degree calculation parts 1520_1 to 1520_401 accurately reflects the condition of the chamber 120.

### Correspondence Relationship between Degree of Deviation and Etching Rate

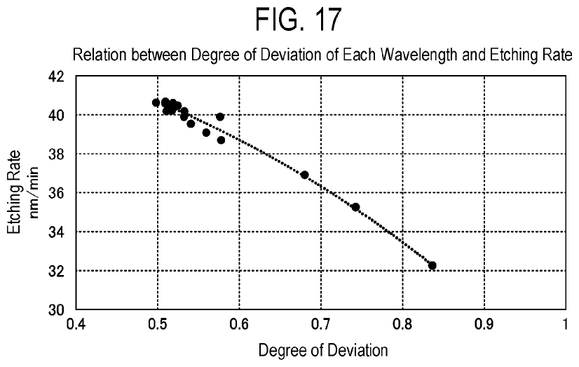

Next, a correspondence relationship between a degree of deviation of entire light emission data of a specific wavelength output from a specific deviation degree calculation part among the deviation degree calculation parts 1520_1 to 1520_401, and an etching rate will be described. FIG. 17 is a diagram illustrating a correspondence relationship between a degree of deviation and an etching rate. In FIG. 17, the horizontal axis represents a degree of deviation (a degree of deviation of the entire emission intensity data of each wavelength), and the vertical axis represents an etching rate. As illustrated in FIG. 17, the degree of deviation of the entire emission intensity data of each wavelength and the etching rate have a substantially linear relationship.

Therefore, by referring to FIG. 17, the conversion part 1530 can specify the etching rate based on the degree of deviation output from a specific deviation degree calculation part.

### Flow of Analysis and Control process

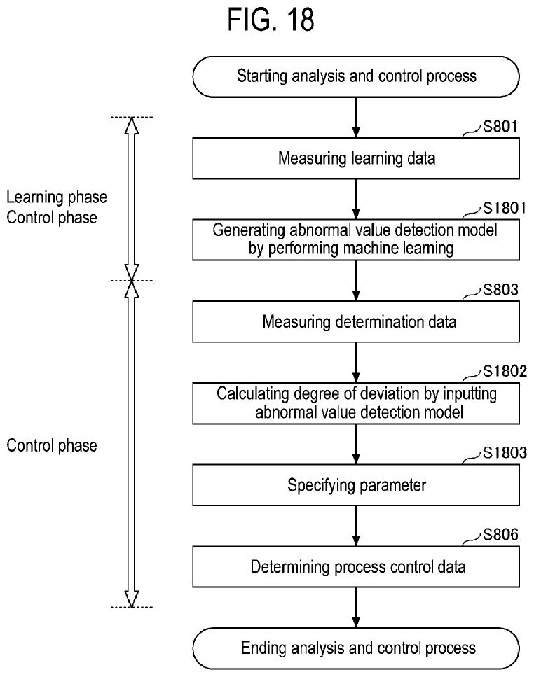

Next, a flow of an analysis and control process in the etching process control system 100′ will be described. FIG. 18 is a second flowchart illustrating a flow of an analysis and control process. Differences from the first flowchart illustrated in FIG. 8 are steps S1801, S1802, and S1803.

In step S1801, the learning part 1400 of the analysis device 150 acquires OES data measured in a normal condition serving as a reference as learning data. The learning part 1400 generates a learned abnormal value detection model by calculating a data density from the emission intensity data of each wavelength included in the acquired OES data, calculating the range of abnormal values, and setting normal range information.

In step S1802, the specifying part 1500 acquires the OES data as determination data, and calculates a degree of deviation of entire emission intensity data of each wavelength by inputting the emission intensity data of each wavelength included in the OES data into the learned abnormal value detection model.

In step S1803, the specifying part 1500 of the analysis apparatus 150 acquires a degree of deviation for a specific wavelength, and based on the acquired degree of deviation, specifies a characteristic value (an etching rate) for determining process control data at the time of an etching process in a control section.

### Summary

As is clear from the above description, the etching process control system according to the fifth embodiment operates as follows:

calculating a degree of deviation of entire emission intensity data of each wavelength by inputting, among OES data measured in the chamber in which a plasma process is performed, OES data measured in a determination section into an abnormal value detection model for each wavelength;

specifying a characteristic value (an etching rate) for determining process control data at the time of an etching process in a control section after the determination section, based on the degree of deviation of the entire emission intensity data calculated for a specific wavelength; and

controlling the etching process in the control section based on the specified characteristic value (the etching rate).

As a result, according to the fifth embodiment, it is possible to provide an analysis device, an analysis method, an analysis program, and an etching process control system for quantitatively evaluating a condition of a processing space in which a plasma process is performed by using OES data measured in the processing space.

### Other Embodiments

In each of the above-described first to fourth embodiments, it has been described that the learning part performs machine learning on a cross-correlation model as an example of a time-series analysis model. However, the model on which the learning part performs machine learning is not limited to the cross-correlation model, and may be another model as long as correlation of time-series data can be calculated.

In addition, in each of the above-described first to fourth embodiments, it has been described that the count part 622 counts the number of first nodes at which a difference calculated by the difference calculation part 621 is equal to or greater than a predetermined threshold value, thereby counting a predetermined count value. However, the method of counting the predetermined count value is not limited thereto. For example, the predetermined count value may be counted by counting a predetermined number of first nodes among the first nodes at which the difference calculated by the difference calculation part 621 is equal to or greater than the predetermined threshold value.

In addition, in each of the above-described embodiments, a case in which an etching rate is specified as a characteristic value for determining process control data at the time of an etching process has been described. However, the characteristic value specified based on a degree of deviation is not limited to the etching rate. Another characteristic value may be specified as long as the characteristic value is a characteristic value (a characteristic value indicating a process variation) used for determining process control data at the time of the etching process and is a characteristic value (a predetermined count value) correlated with the degree of deviation.

In addition, in each of the above-described embodiments, a case in which a characteristic value for determining process control data at the time of an etching process is specified has been described. However, the characteristic value specified based on the degree of deviation is not limited to the characteristic value for determining process control data at the time of the etching process, but may be a characteristic value for determining process control data at the time of a plasma process of a substrate. In addition, “at the time of a plasma process of a substrate” referred to herein includes at the time of a film formation process, at the time of an ashing process, and the like, in addition to at the time of an etching process.

In the above-described second and fifth embodiments, it has been described that learning data is generated for the emission intensity data of each wavelength included in the wavelength range of visible light. However, the emission intensity data used for generating the learning data may be emission intensity data of a specific wavelength. In addition, emission intensity data of a wavelength outside the wavelength range of visible light may also be used.

In the above-described second embodiment, OES data has been described as a specific example of a time-series data group, and in the above-described third embodiment, a process data group has been described as a specific example of a time-series data group. However, the time-series data group is not limited thereto. For example, a time-series data group indicating plasma physical quantities measured by a plasma apparatus may also be used. Similarly, in the fifth embodiment, OES data is given as a specific example of a time-series data group, but the time-series data group is not limited thereto. For example, a process data group may be used, or a time-series data group indicating a plasma physical quantity measured by a plasma device may also be used.

In the above-described fifth embodiment, a case of using an abnormal value detection model has been described, but another model that detects an abnormal value of data based on a data density of each time-series data may also be used.

In each of the above-described embodiments, the analysis device and the controller are configured separately, but the analysis device and the controller may be configured integrally. In each of the above-described embodiments, the controller and the semiconductor manufacturing process are configured separately, but the controller and the semiconductor manufacturing process may be configured integrally.

The present disclosure is not limited to the configurations illustrated herein, such as combinations of other elements in a configuration or the like illustrated in the above-described embodiments. These points can be changed without departing from the gist of the present disclosure, and can be appropriately determined according to an application form thereof.

According to the present disclosure, it is possible to provide an analysis device, an analysis method, an analysis program, and a plasma process control system for quantitatively evaluating a condition of a processing space in which a plasma process is performed, by using a time-series data group measured in the processing space.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An analysis device comprising:
a calculation part configured to calculate a degree of deviation of a processing space, in which a plasma process is performed, from a reference condition by inputting, among time-series data groups measured in the processing space, a time-series data group measured in a determination section, which is a predetermined period of time before a control section, into a time-series analysis model; and
a specifying part configured to specify a characteristic value for determining control data at a time of the plasma process of a substrate in the control section based on the calculated degree of deviation.

2. The analysis device of claim 1, further comprising a learning part configured to perform machine learning on the time-series analysis model by using a time-series data group measured when an etching process was performed in the processing space under the reference condition and to calculate a value indicating a relationship between time-series data of a first node and time-series data of a second node, wherein the calculation part is further configured to calculate the degree of deviation based on a number of first nodes at which a difference between time-series data of the second node inferred by inputting the time-series data of the first node extracted from the time-series data group measured in the determination section into the time-series analysis model, and time-series data of the second node extracted from the time-series data group measured in the determination section is equal to or greater than a predetermined threshold value.

3. The analysis device of claim 2, wherein the specifying part is further configured to specify an etching rate for determining control data at a time of an etching process in the control section after the determination section based on the calculated degree of deviation.

4. The analysis device of claim 3, wherein the determination section is a predetermined period of time after a plasma source is turned on in an etching process, and the control section is a section for the etching process after the determination section.

5. The analysis device of claim 3, wherein the determination section is a predetermined period of time before starting an etching process, and the control section is a section from a start to an end of the etching process.

6. The analysis device of claim 1, wherein the specifying part is further configured to specify an etching rate for determining control data at a time of an etching process in the control section after the determination section based on the calculated degree of deviation.

7. The analysis device of claim 1, wherein the determination section is a predetermined period of time after a plasma source is turned on in an etching process, and the control section is a section for the etching process after the determination section.

8. The analysis device of claim 1, wherein the determination section is a predetermined period of time before starting an etching process, and the control section is a section from a start to an end of the etching process.

9. The analysis device of claim 1, wherein the time-series data group is optical emission spectroscopy (OES) data measured by an emission spectrometric analyzer or mass analysis data measured by a mass analyzer.

10. The analysis device of claim 1, wherein the time-series data group is a process data group measured by a process data acquisition device.

11. The analysis device of claim 1, wherein the time-series data group is a time-series data group of plasma physical quantities measured by a plasma apparatus.

12. The analysis device of claim 2, wherein the value indicating the relationship includes an autocorrelation, a cross-correlation, or a time delay, which is calculated such that the time-series data of the second node is derived by inputting the time-series data of the first node into a predetermined equation.

13. The analysis device of claim 1, wherein the calculation part is further configured to calculate the degree of deviation by using abnormal value detection models instead of the time-series analysis model, the number of the abnormal value detection models corresponding to the number of types of time-series data included in the time-series data group.

14. The analysis device of claims 13, wherein the specifying part is further configured to specify the characteristic value from the degree of deviation, which is calculated based on binary information indicating presence or absence of an abnormal value determined by a specific one of the abnormal value detection models.

15. A plasma process control system comprising:
a chamber serving as a processing space in which a plasma process of a substrate is performed;
a plasma source configured to form plasma in the processing space;
a calculation part configured to calculate a degree of deviation of the processing space from a reference condition by inputting, among time-series data groups measured in the processing space, a time-series data group measured in a determination section, which is a predetermined period of time before a control section, into a time-series analysis model;
a specifying part configured to specify a characteristic value for determining control data at a time of the plasma process of the substrate in the control section based on the calculated degree of deviation; and
a controller configured to determine the control data at the time of the plasma process of the substrate based on the characteristic value.

16. A non-transitory computer-readable recording medium storing an analysis program that causes a computer to execute:
calculating a degree of deviation of a processing space, in which a plasma process is performed, from a reference condition by inputting, among time-series data groups measured in the processing space, a time-series data group measured in a determination section, which is a predetermined period of time before a control section, into a time-series analysis model; and
specifying a characteristic value for determining control data at a time of the plasma process of a substrate in the control section based on the calculated degree of deviation.
